(19) United States
(12) Patent Application Publication
(10) Pub. No.: US 2024/0395734 A1
(43) Pub. Date: Nov. 28, 2024

(54) ELECTRONIC DEVICE

(71) Applicant: TAIWAN SEMICONDUCTOR MANUFACTURING COMPANY, LTD., Hsinchu (TW)

(72) Inventors: Tien-Wei CHIANG, Hsinchu (TW); Po-Sheng LU, Hsinchu (TW); Yuan-Jen LEE, Hsinchu (TW); Nuo XU, Hsinchu (TW)

(73) Assignee: TAIWAN SEMICONDUCTOR MANUFACTURING COMPANY, LTD., Hsinchu (TW)

(21) Appl. No.: 18/322,045

(22) Filed: May 23, 2023

(51) Int. Cl. H01L 23/60; H01L 23/12; H10B 61/00; H10N 50/85

(52) U.S. Cl. CPC H01L 23/60; H01L 23/12; H10B 61/00; H10N 50/85

(57) ABSTRACT

An electronic device includes a printed circuit board, a semiconductor chip, and a shielding unit. The semiconductor chip is mounted and electrically connected to the printed circuit board, and includes a magnetic memory element. The shielding unit includes a magnetic material, and is mounted to the printed circuit board to at least partially cover the magnetic memory element so as to reduce interference from an external magnetic field on the magnetic memory element.

### BACKGROUND

A magnetic memory utilizes magnetized medium to store data, and can provide many advantages, such as a low read and write power, a fast switching speed, a high reliability, and a long retention time. However, the memory state of the magnetic memory could be disturbed by application of an external magnetic field, such as magnets placed around the magnetic memory, which may cause increased bit error rates during retention or switching of the memory state in the magnetic memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an electronic device in accordance with some embodiments.

FIG. 2 is a schematic perspective view of the electronic device shown in FIG. 1 in accordance with some embodiments.

FIG. 3 is a schematic cross sectional view of the electronic device taken along line A-A of FIG. 2 in accordance with some embodiments.

FIG. 4 is a schematic top view of an electronic device in accordance with some other embodiments.

FIG. 5 is a schematic cross sectional view of the electronic device shown in FIG. 4 in accordance with some other embodiments.

FIG. 6 is a schematic cross sectional view of an electronic device in accordance with still some other embodiments.

FIG. 7 is a schematic cross sectional view of an electronic device in accordance with yet some other embodiments.

FIGS. 8 to 10 are bar charts each illustrating magnetic flux densities of different samples of electronic devices.

FIG. 11 is a line graph illustrating a normal required spin-transfer-torque efficiency at different magnetic immunity for electronic devices in three different cases.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

The present disclosure is directed to an electronic device that includes a printed circuit board, a shielding unit mounted onto the printed circuit board, and a magnetic memory element which is at least partially covered by the shielding unit. The shielding unit includes a magnetic material, so as to effectively direct any external magnetic field to pass through the shielding unit, thereby reducing interference of the external magnetic field on the magnetic memory element. The present disclosure may be regarded as a board-level magnetic shielding design which describes the configuration that the shielding unit is fabricated on an existing printed circuit board without involving a complicated manufacturing and/or packaging process, and may provide an effective shielding effect to the magnetic memory element. The electronic device may be any suitable product application using a magnetic memory, such as smart phones/watches, Internet of things (IoT) devices, virtual reality (VR)/augmented reality (AR) applications, automobiles, but are not limited to. Other suitable applications serving as the electronic device are within the contemplated scope of the present disclosure. The external magnetic field may be a static (DC) magnetic field, or a low frequency (e.g., substantially less than 1 kHz) magnetic field. The external magnetic field may be generated from a magnet around the magnetic memory element. For instance, in some cases, the magnet may be a built-in magnet located inside the electronic device, and/or an extrinsic magnet located outside the electronic device. In other cases, the external magnetic field may be generated from power lines, or other electronic devices.

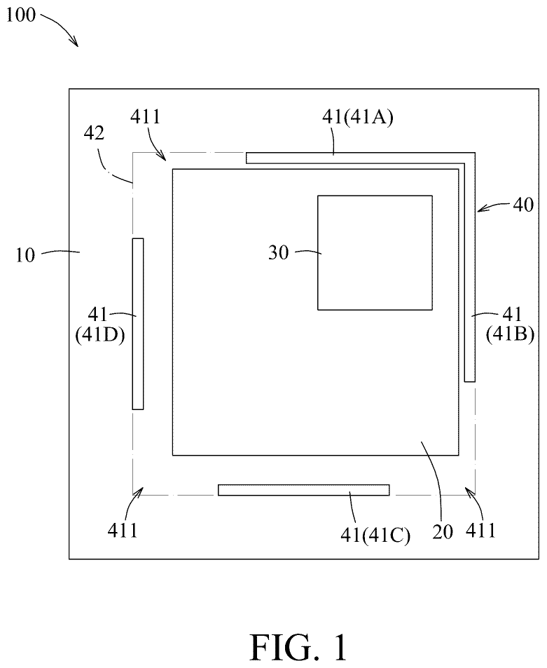

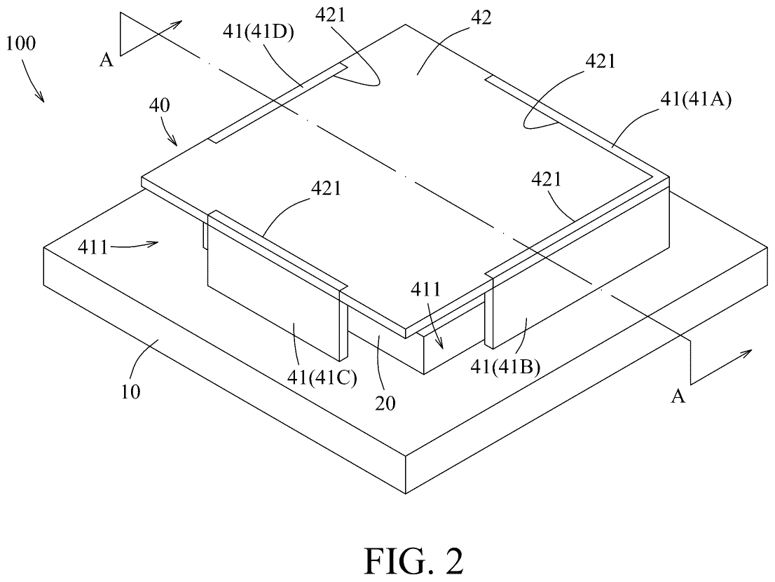

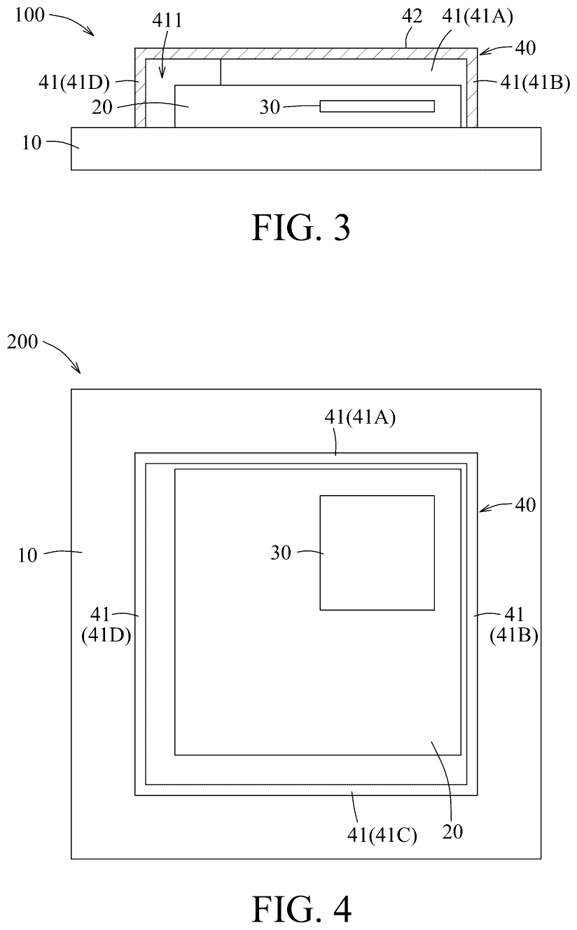

FIGS. 1 to 3 are schematic views illustrate an electronic device 100 in accordance with some embodiments. FIG. 1 is a schematic top view of the electronic device 100 in accordance with some embodiments, in which a ceiling wall 42 of a shielding unit 40 is illustrated by an imaginary line. FIG. 2 is a schematic perspective view of the electronic device 100 in accordance with some embodiments. FIG. 3 is a schematic cross sectional view of the electronic device 100 taken along line A-A of FIG. 2 in accordance with some embodiments.

Referring to FIGS. 1 to 3, an electronic device 100 in accordance with some embodiments of the present disclosure includes a printed circuit board 10, a semiconductor chip 20 including a magnetic memory element 30, and a shielding unit 40.

The printed circuit board 10 is configured to connect different electronic components mounted thereon with each other (e.g., the printed circuit board 10 may function to connect the semiconductor chip 20 with other electronic components (not shown)), and to allow assembly of the shielding unit 40 and the semiconductor chip 20 (will be discussed later). The printed circuit board 10 may be made of any suitable materials and/or processes. The printed circuit board 10 may be single-sided, or double sided. The printed circuit board 10 may have a size determined according to product design and practical needs, as well as application of the electronic device 100.

The semiconductor chip 20 including the magnetic memory element 30 is mounted on the printed circuit board 10 so as to be electrically connected to circuits (not shown) on the printed circuit board 10, as well as other electronic components, if any, mounted on the printed circuit board 10. The semiconductor chip 20 may further include any suitable semiconductor structures, such as integrated circuits, based on product design and practical needs.

The magnetic memory element 30 may be located on a surface of the semiconductor chip 20, or may be embedded therein. In some embodiments, the magnetic memory element 30 is a magneto-resistive random access memory (MRAM). Examples of the magnetic memory element 30 includes spin-transfer torque-MRAM (STT-MRAM), spin-orbit torque-MRAM (SOT-MRAM), Toggle-MRAM, but are not limited thereto. Other suitable magnetic memory elements are within the contemplated scope of the present disclosure.

The shielding unit 40 is mounted onto the printed circuit board 10 to at least partially cover the magnetic memory element 30. The shielding unit 40 is configured to provide a shielding effect to the magnetic memory element 30 by reducing interference from an external magnetic field on the magnetic memory element 30.

The shielding unit 40 may be mounted onto the printed circuit board 10 using any suitable methods such as welding, bonding through, for example, adhesive, or fastening with, for example, screws, but are not limited thereto. Other methods for mounting the shielding unit 40 onto the printed circuit board 10 are within the contemplated scope of the present disclosure. In a manufacturing process of the electronic device 100, in some cases, the shielding unit 40, and the semiconductor chip 20 including the magnetic memory element 30 are separately formed, and are then mounted to the printed circuit board 10 in an assembling step. Such manufacturing process is conducive to producing high quality electronic device 100 because, formation of the shielding unit 40 is usually conducted at a relatively high temperature which is challenging for the semiconductor chip 20 and the magnetic memory element 30 to remain undamaged under such high thermal energy. However, when the shielding unit 40 is formed at relatively low temperature, lattice defect might be formed therein, and could undesirably lower mechanical reliability of the electronic device 100 produced thereby. Thus, in some embodiments, formation of the shielding unit 40 is independent of formation of the semiconductor chip 20 and formation of the magnetic memory element 30, so as to maintain thermal and mechanical reliability of the electronic device 100 produced thereby. In addition, such manufacturing process is relatively simple, and may be conducted at a relatively low fabrication cost.

The shielding unit 40 may include a ceiling wall 42 that is disposed on the magnetic memory element 30 opposite to the printed circuit board 10, and a plurality of supporting walls 41 that support the ceiling wall 42, so as to permit the ceiling wall 42 to be disposed over the magnetic memory element 30. For instance, as shown in FIG. 1, there are four supporting walls 41, which are respectively located on a front side of, on a right side of, at a rear side of, and on a left side of the semiconductor chip 20 (and which are respectively positioned at an upper portion, a right portion, a lower portion and a left portion in FIG. 1, and which are respectively referred as the front, the right, the rear and the left supporting walls 41A, 41B, 41C, 41D hereinafter). In other embodiments, there may be more, or fewer supporting walls 41 around the semiconductor chip 20, and number of supporting walls 41 may be varied based on product design and practical needs. In some embodiments, the ceiling wall 42 has four cut-out portions 421, and each of the supporting walls 41 has a lower end mounted on the printed circuit board 10, and an upper end fittingly engaged in a respective one of the cut-out portions 421.

In some embodiments, the shielding unit 40 includes a magnetic material. The magnetic material may have a high permeability (μᵣ) and a high magnetization (Bₛ), so that a greater amount of an external magnetic field could be directed to pass through the shielding unit 40 in an effective manner. Examples of the magnetic material may include, for example but not limited to, silicon steel, manganese zinc, cobalt iron, nickel iron, and combinations thereof. Other suitable materials for the shielding unit 40 are within the contemplated scope of the present disclosure.

In some embodiments, the entire shielding unit 40, i.e., the ceiling wall 42, and each of the supporting walls 41, are made of the magnetic material. In other embodiments, a part of the shielding unit 40 is made of the magnetic material, while a remaining part of the shielding unit 40 is made of a non-magnetic material. For instance, in some cases, the ceiling wall 42 is made of the magnetic material, whereas the supporting walls 41 are made of the non-magnetic material. In some other cases, one or more of the supporting walls 41 are made of the non-magnetic material, and the ceiling wall 42 and the remaining supporting wall(s) 41 are made of the magnetic material. Material for each part of the shielding unit 40 may be different from each other and may be determined based on product design and practical needs. Please note that, the shielding effect is mainly provided by part(s) of the shielding unit 40 that is (are) made of the magnetic material, while part(s) of the shielding unit 40 that is (are) made of the non-magnetic material do not substantially contribute to the shielding effect.

In some embodiments, at least some adjacent ones of the supporting walls 41 are spaced apart from each other to form a spacing 411 between the spaced apart supporting walls 41. In other embodiments, at least some adjacent ones of the supporting walls 41 are connected to each other. For instance, referring to the shielding unit 40 shown in FIGS. 1 and 2, the front and the right supporting walls 41A, 41B are connected to each other to form a corner covering a front right portion of the semiconductor chip 20 and a front right portion of the magnetic memory element 30, while the left and the rear supporting walls 41D, 41C are spaced apart from each other, and are spaced apart from the front and the right supporting walls 41A, 41B. Number of the supporting walls 41 that are connected and/or disconnected to each other, and/or configuration of the connected/disconnected supporting walls 41 may be varied based on product design and practical needs. Please note that when the number of the supporting walls 41 connected to each other is greater, or when the spacing 411 present between any two of the adjacent supporting walls 41 is smaller, the shielding unit 40 provides a more complete enclosure to the magnetic memory element 30, and thus a more enhanced shielding effect to the magnetic memory element 30 is achieved.

In some embodiments, the semiconductor chip 20 including the magnetic memory element 30 abuts the shielding unit 40, i.e., the semiconductor chip 20 (or the magnetic memory element 30 that is located on a surface of the semiconductor chip 20) is in direct contact with the shielding unit 40. In other embodiments, the semiconductor chip 20 including the magnetic memory element 30 is spaced apart from the shielding unit 40, i.e., the semiconductor chip 20 and the magnetic memory element 30 are not in direct contact with the shielding unit 40. Distance between the magnetic memory element 30 (or the semiconductor chip 20) and the shielding unit 40 may be determined based on product design and practical needs. Please note that when the magnetic memory element 30 is arranged closer to the shielding unit 40, the shielding effect provided by the shielding unit 40 is found to be more effective.

The shielding unit 40 may have a size not greater than the printed circuit board 10, so that the shielding unit 40 is mounted onto the printed circuit board 10. Considering that the printed circuit board 10 has a top surface on which the semiconductor chip 20 and the shielding unit 40 are mounted, the shielding unit 40 occupies an area on the top surface of the printed circuit board 10, and the occupied area of the shielding unit 40 ranges from a first value to a second value. When the occupied area of the shielding unit 40 is the first value, the shielding unit 40 is configured to permit the semiconductor chip 20 to be fitted thereinside, i.e., inner surfaces of the supporting walls 41 abut side surfaces of the semiconductor chip 20, respectively. When the occupied area of the shielding unit 40 is the second value, the occupied area of the shielding unit 40 is a surface area of the top surface of the printed circuit board 10. i.e., outer surfaces of the supporting walls 41 opposite to the semiconductor chip 20 are flush with side surfaces of the printed circuit board 10, respectively. Please note that, size and thickness of the shielding unit 40 may be adjusted according to product design and practical needs.

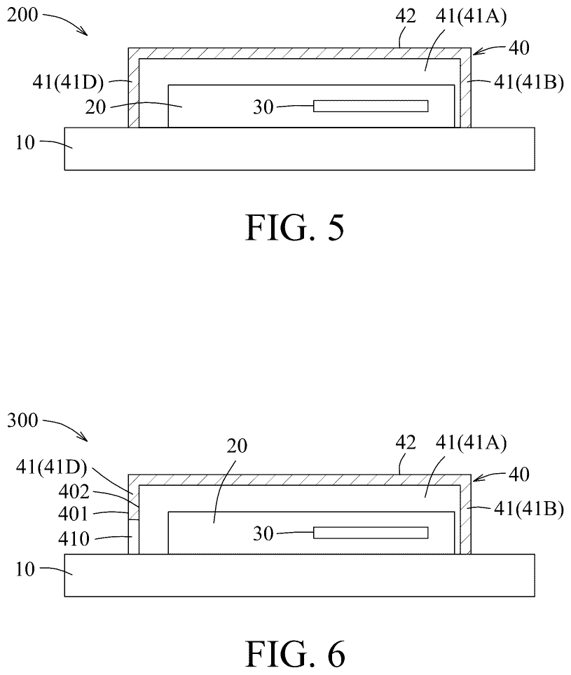

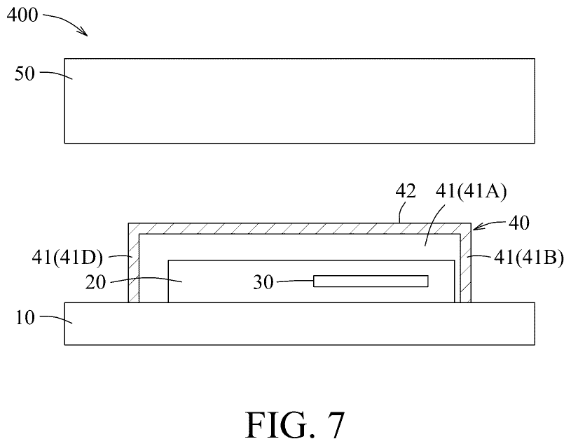

In addition, a position, a thickness, a width and/or a length of each of the supporting walls 41 on the printed circuit board 10 may be adjusted according to product design and practical needs. For instance, in the exemplary electronic device 100 shown in FIG. 1, the left and the rear supporting walls 41D, 41C are respectively located in a center position of a left edge and a rear edge of the printed circuit board 10, the right supporting wall 41B is located at a front portion of a right edge of the printed circuit board 10, and the front supporting wall 41A is located at a right portion of a front edge of the printed circuit board 10. In addition, as shown in FIG. 1, the supporting walls 41 are comparatively short. In some embodiments, the supporting walls 41 may be formed with reduced length so as to meet processing requirements or product design. In other embodiments, the supporting walls 41 are formed to have greater length such that the spacing 411 between adjacent supporting walls is smaller, so as to provide more a complete enclosure to the magnetic memory element 30, as exemplified by another electronic device 200 shown in FIGS. 4 to 5. A relative dimension among the printed circuit board 10, the semiconductor chip 20 and the magnetic memory element 30 may be varied according to product design and practical needs.

FIGS. 4 and 5 are schematic views illustrating an electronic device 200 in accordance with some embodiments. FIG. 4 is similar to FIG. 1, illustrating a schematic top view of the electronic device 200 excluding the ceiling wall 42 of a shielding unit 40 in accordance with some embodiments. FIG. 5 is similar to FIG. 3, illustrating a schematic cross sectional view of the electronic device 200 in accordance with some embodiments. Referring to FIGS. 4 and 5, the electronic device 200 is similar to the electronic device 100 shown in FIGS. 1 to 3, except that each of the supporting walls 41 of the electronic device 200 is comparatively longer, and the supporting walls 41 are connected to each other so as to permit the shielding unit 40 to fully enclose the semiconductor chip 20 on the printed circuit board 10.

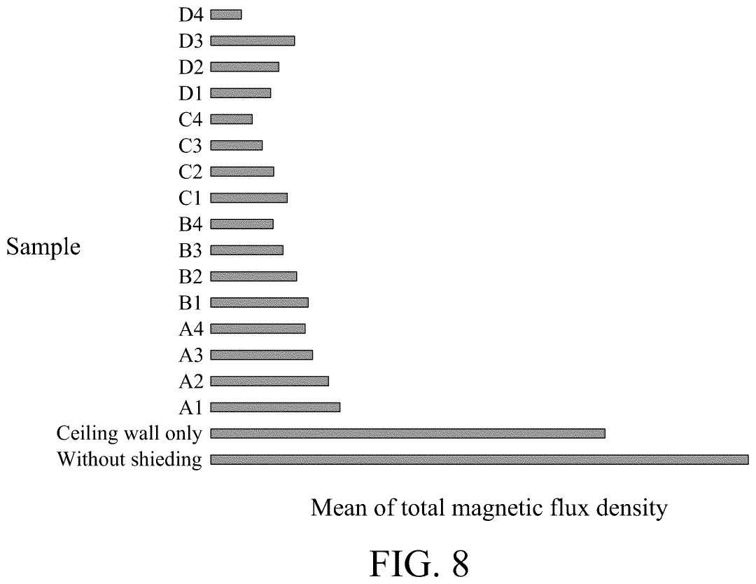

FIG. 6 is similar to FIGS. 3 and 5, illustrating a schematic cross sectional view of an electronic device 300 in accordance with some embodiments. Referring to FIG. 6, the electronic device 300 is similar to the electronic device 200 shown in FIG. 5, except that the shielding unit 40 is formed with a through hole 410 (see the left supporting wall 41D). Considering the shielding unit 40 has an outer surface 401 distal from the magnetic memory element 30 and the semiconductor chip 20, and an inner surface 402 opposite to the outer surface 401, the through hole 410 may be formed to extend from the outer surface 401 to the inner surface 402. Please note that, a number, a size and a position of the through hole 410 may be determined based on product design and practical needs.

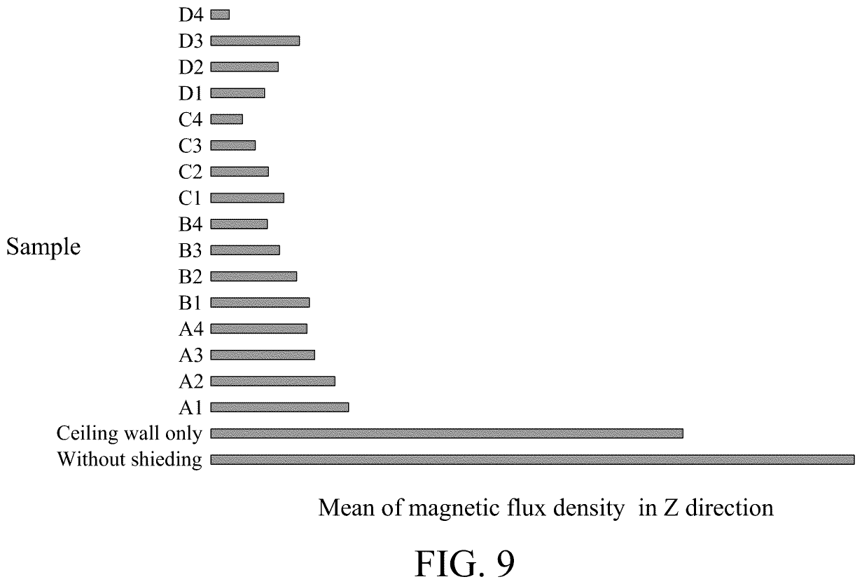

FIG. 7 illustrates a schematic cross sectional view of an electronic device 400 in accordance with some embodiments. The electronic device 400 is similar to the electronic device 200 shown in FIG. 5, except that the electronic device 400 further includes a magnet 50 which is disposed to be spaced apart from the printed circuit board 10. In some embodiments, the magnet 50 might be a built-in magnet configured to align with an aligning magnet located outside the electronic device 400. Such electronic device 400 could be applied in, for example, but are not limited to, wireless charging devices. Other suitable examples of the magnet 50 and/or applications of the electronic device 400 are within the contemplated scope of the present disclosure. The magnet 50 unavoidably generates an external magnetic field causing interference to the magnetic memory element 30. Since such interference is comparatively controllable and predictable, adjustment in different aforementioned parameters of the shielding unit 40 may effectively reduce interference from the external magnetic field of the magnet 50, so as to ensure normal operation of the magnetic memory element 30.

Apart from the interference from the built-in magnet, a more uncontrollable and unpredictable interference to the magnetic memory element 30 is an extrinsic magnet that is located outside the electronic device 400, and that is either intentionally or unintentionally brought near the electronic device. In the electronic devices 100, 200, 300 and 400 according to the present disclosure, the shielding unit 40 made of the magnetic material at least partially covers the magnetic memory element 30, so that when the extrinsic magnet is brought near, an external magnetic field generated by the extrinsic magnet is directed to pass through the shielding unit 40 instead of passing through the magnetic memory element 30, so as to reduce interference from the external magnetic field on the magnetic memory element 30, thereby providing a shielding effect to the magnetic memory element 30. The shielding unit 40 also provides shielding effect to the magnetic memory element 30 against the built-in magnet, i.e., the magnet 50 mentioned with reference to FIG. 7, in a similar manner.

The shielding effect may be varied by optimizing the geometry of the shielding unit 40, so as to further enhance shielding effect thereof, thereby fulfilling different practical needs and product design. As aforementioned, the length/the width/the thickness of each of the supporting walls and/or the ceiling wall of the shielding unit 40 may be adjusted (see FIGS. 1 and 4). The number/spacing/position/configuration of each of the supporting walls may be adjusted. The distance between the shielding unit 40 and the magnetic memory element 30 may be adjusted. Material of each part of the shielding unit 40 may be different from each other. The through hole(s) 410 may be formed at different position(s) in the shielding unit 40 (see FIG. 6). Other suitable adjustments on the geometry of the shielding unit 40 are within the contemplated scope of the present disclosure.

In the following description, a simulation of an external magnetic field provided by a magnet on the interference of the magnetic memory element when adopting different geometries of the shielding unit is performed. To be specific, 16 samples of electronic devices (samples A1 to A4, B1 to B4, C1 to C4 and D1 to D4) are prepared, each of which is similar to the electronic device 100 shown in FIGS. 1 to 3, except that the supporting walls of the shielding units are formed with different lengths. In addition, the shielding units of the 16 samples are entirely made of a magnetic material. For each of the samples, (i) the front and the right supporting walls have the same length which is referred to as an X value, and (ii) the rear and the left supporting walls have the same length which is referred to as a Y value. The samples are arranged into four different groups, namely, A, B, C, and D. In the same group, the X values for the four different samples are the same (X1 for group A, X2 for group B, X3 for group C, and X4 for group D), and the Y values for the four different samples are respectively Y1, Y2, Y3, and Y4 (Y1<Y2<Y3<Y4). For the samples having the same Y value (Y1, Y2, Y3 or Y4), the X values for groups A, B, C and D are respectively X1, X2, X3 and X4 (X1<X2<X3<X4). The X and Y values are also listed in Table 1 below.

Besides, another sample labeled “Ceiling wall only” has a configuration similar to the electronic device 100 shown in FIGS. 1 to 3, except that, for the shielding unit of the “Ceiling wall only” sample, the ceiling wall is made of the magnetic material, while the supporting walls are made of the non-magnetic material.

Yet another sample labeled “Without shielding” that is formed without the shielding unit is prepared.

TABLE 1

| Sample | X value | Y value |
|---|---|---|
| No shielding | — | — |
| Ceiling wall only | — | — |
| A1 | X1 | Y1 |
| A2 | X1 | Y2 |
| A3 | X1 | Y3 |
| A4 | X1 | Y4 |
| B1 | X2 | Y1 |
| B2 | X2 | Y2 |
| B3 | X2 | Y3 |
| B4 | X2 | Y4 |
| C1 | X3 | Y1 |
| C2 | X3 | Y2 |
| C3 | X3 | Y3 |
| C4 | X3 | Y4 |
| D1 | X4 | Y1 |
| D2 | X4 | Y2 |
| D3 | X4 | Y3 |
| D4 | X4 | Y4 |

Note:
(i) X1 < X2 < X3 < X4
(ii) Y1 < Y2 < Y3 < Y4
(iii) “—” denotes not applicable

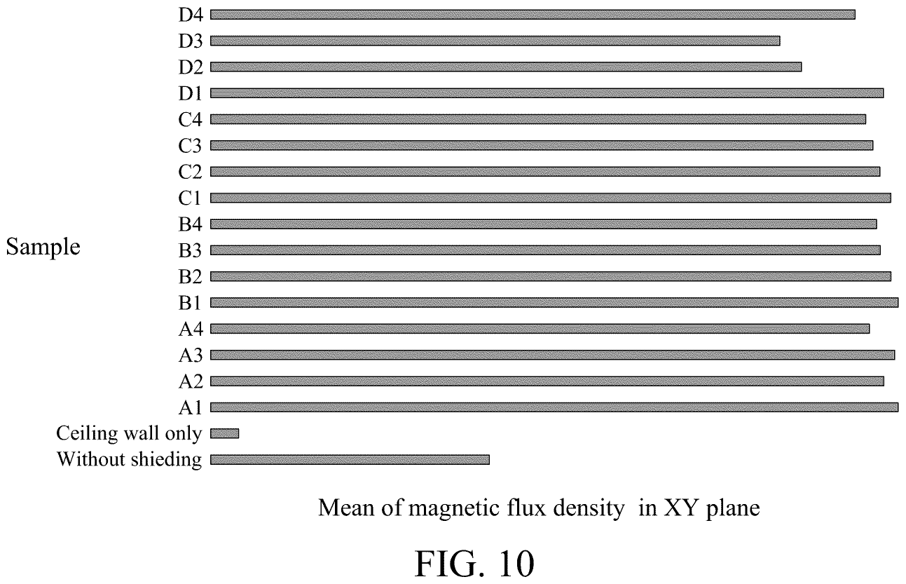

For each of the samples, a magnet is placed thereon (at a distance of substantially a few millimeters away from top surfaces of the samples), and the external magnetic field received by the magnetic memory element is simulated, and analyzed in terms of magnetic flux density (in unit of Gauss). FIGS. 8 to 10 respectively show the result of a mean of total magnetic flux density, a mean of magnetic flux density in a Z direction (perpendicular to a top surface of the printed circuit board), and a mean of magnetic flux density in a XY plane (parallel to the top surface of the printed circuit board).

Referring to FIG. 8, it can be found that with the provision of the shielding unit, a mean of the total magnetic flux density of the magnetic memory element is significantly lower than a mean of the total magnetic flux density the “Without shielding” sample. In accordance with some embodiments, an effective magnetic field received by the samples including the shielding unit decrease by substantially more than 30% when compared with the “Without shielding” sample. Therefore, the shielding unit may effectively provide a shielding effect to the magnetic memory element and the external magnetic field generated by the magnet may be directed to pass through the shielding unit, so that the magnetic memory element endures a significantly reduced interference from the magnet.

In addition, among the samples including the shielding unit, the mean of the total magnetic flux density of the magnetic memory element in each of the samples of groups A, B, C and D is lower than the mean of the total magnetic flux density of the magnetic memory element in the “Ceiling wall only” sample. It can be found that when the entire shielding unit is made of the magnetic material, such shielding unit provides an even more effective shielding effect to the magnetic memory element, and thus interference to the magnetic memory element is further reduced.

Moreover, for the four samples in the same group, the mean of the total magnetic flux density of the magnetic memory element is substantially decreased with the increase of the Y value. For the samples having the same Y value, the mean of the total magnetic flux density of the magnetic memory element is substantially decreased with the increase of the X value. It can be noted that, when the lengths of the supporting walls increase, or when the spacing between two adjacent supporting walls becomes smaller, the shielding unit provides a more complete enclosure to the magnetic memory element, and thus a more effective shielding effect to the magnetic memory element is provided, thereby further reducing interference to the magnetic memory element.

Referring to FIG. 9, in the Z direction, each of the samples in groups A, B, C and D has a comparatively lower mean of magnetic flux density. Referring to FIG. 10, in the XY plane, each of the samples in groups A, B, C and D has a comparatively greater mean of magnetic flux density. This could be due to the external magnetic field generated by the magnet is first directed to pass through the ceiling wall, then travels along the XY plane and tends to be further directed to the supporting walls, resulting in a comparatively large magnetic flux density in the XY plane, whereas the magnetic flux density remaining in the Z direction is comparatively low. Despite of the results shown in FIGS. 9 and 10, the overall shielding effect could be mainly determined based on the mean of the total magnetic flux density shown in FIG. 8.

The shielding effect exerted on the magnetic memory element may be represented by a shielding factor (SF). SF is known as a ratio between a total magnetic field received by a magnetic memory element without any shielding and the total magnetic field received by a magnetic memory element shielded by the shielding unit. It is noted that the magnetic memory element with a larger SF receives a smaller magnetic field, and thus has an improved magnetic immunity (the magnetic memory element has improved ability to be operated normally in the presence of an interfering magnet).

Performance of the electronic device may also be determined by a spin-transfer-torque (STT) efficiency thereof, which is known as a ratio between a retention energy (Δ) required to retain a data in the magnetic memory element, and a write current (I_{w}) for performing a writing operation. When the STT efficiency to be acquired is lower, process difficulties that need to be overcome during a manufacturing process is also lower. In the manufacturing process of the electronic device, a STT efficiency design target is to be fulfilled so as to ensure a satisfactory performance thereof, especially under interference of a built-in magnet or an extrinsic magnet. However, it is noted that, when such built-in magnet or extrinsic magnet causes interference to the magnetic memory element, the magnetic memory element might have a smaller retention energy, and/or, a greater writing current, than that of the magnetic memory element without interference, resulting in a STT efficiency that does not fulfill the STT efficiency design target. Therefore, in order to manufacture the electronic device having the magnetic memory element with improved magnetic immunity, the magnetic memory element thus produced has a STT efficiency requirement even higher than the STT efficiency design target (e.g., through reaching a higher retention energy and/or a lower writing current), and thus process difficulties during the manufacturing process also undesirably increase. In this disclosure, the magnetic immunity of the magnetic memory element can be improved by simply including the shielding unit, without increasing the process difficulties. This would be further explained in the following paragraphs.

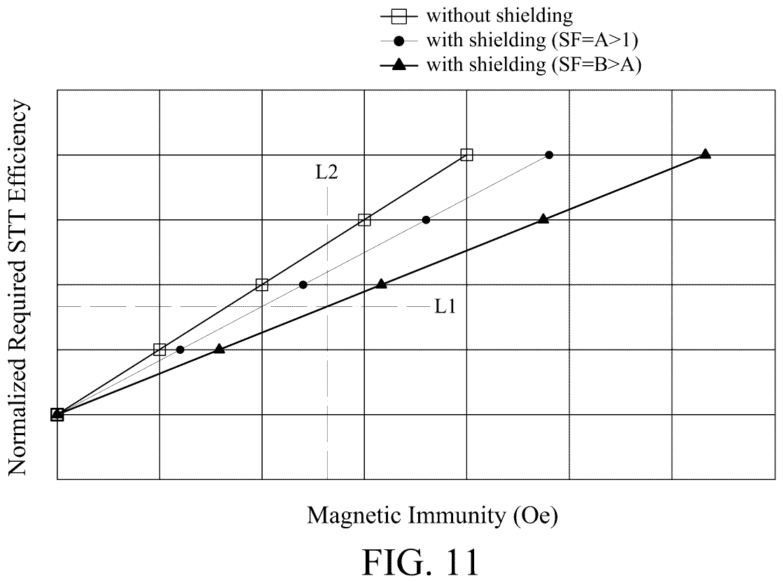

FIG. 11 is a line graph illustrating a normalized required spin-transfer-torque (STT) efficiency at different magnetic immunity in three different cases, which respectively have (i) no shielding unit (denoted as “Without shielding”), (ii) the shielding unit and a SF=A>1 (denoted as “With shielding (SF=A>1)”), and (iii) the shielding unit and a SF=B>A (denoted as “With shielding (SF=B>A)”). For all three cases, when the magnetic memory element is designed to have a higher magnetic immunity, the STT efficiency requirement is also higher, and vice versa.

When a certain STT efficiency (represented by line L1 in FIG. 11) is required, the two electronic devices, each including the shielding unit, are found to have improved magnetic immunity than that of the electronic device that does not include the shielding unit. In other words, by including the shielding unit, the electronic device of the present disclosure effectively achieves an improved magnetic immunity under the same STT efficiency requirement.

When a certain magnetic immunity (represented by line L2 in FIG. 11) is required, the two electronic devices, each including the shielding unit, are found to have STT efficiency requirement smaller than that of the electronic device that does not include the shielding unit. In other words, to achieve the same magnetic immunity, by including the shielding unit, the STT efficiency required by the electronic device of the present disclosure is smaller, and thus process difficulties are reduced.

In addition, when comparing the two electronic devices, each including the shielding unit, but with different geometry and different SF, the one having a greater SF is found to have a less steep slope, indicating a further enhancement of magnetic immunity, or a further reduction in STT efficiency required. This shows that, by performing an optimization process on the geometry of the shielding unit, the shielding unit may have an improved shielding effect, and thus the magnetic memory element shielded by the shielding unit can have a greater SF, thereby allowing the magnetic memory element in the electronic device of the present disclosure to have an improved performance in terms of improved magnetic immunity and reduced STT efficiency requirement. In some embodiments, the magnetic memory element of the electronic device in accordance with some embodiments may have a SF greater than about 1.5. As aforementioned, an optimization process on the geometry of the shielding unit 40 may include, for example, but not limited to, altering a thickness of the shielding unit, a length of each of the supporting walls, a distance between the magnetic memory element and the shielding unit, and/or a spacing between any two of adjacent ones of the supporting walls, so as to achieve a more complete enclosure of the magnetic memory element. In addition, when more parts of the shielding unit 40 adopt the magnetic material, a more effective shielding effect is provided by the shielding unit.

The embodiments of the present disclosure have the following advantageous features. By including the shielding unit, an external magnetic field generated from a built-in or an extrinsic magnet is effectively directed to the shielding unit instead of passing through the magnetic memory chip, so that the magnetic memory chip is protected from the interference of the external magnetic field. As a result, a bit error rate due to retention and read disturbance can be effectively reduced. In addition, the magnetic immunity of the magnetic memory element in the electronic device of the present disclosure is improved, and the STT efficiency required is reduced, which is conducive in reducing process difficulties. Moreover, the shielding unit is flexible to adopt different immunity specification and/or different geometries, and allows the electronic device to be used in a variety of product applications, especially those with a relatively small size. Furthermore, the shielding unit and the semiconductor chip are independently produced, resulting in a relatively simple manufacturing process, and the electronic device produced thereby is thermally and mechanically reliable.

In accordance with some embodiments of the present disclosure, an electronic device includes a printed circuit board, a semiconductor chip, and a shielding unit. The semiconductor chip is mounted and electrically connected to the printed circuit board, and includes a magnetic memory element. The shielding unit includes a magnetic material, and is mounted to the printed circuit board to at least partially cover the magnetic memory element so as to reduce interference from an external magnetic field on the magnetic memory element.

In accordance with some embodiments of the present disclosure, the shielding unit includes a ceiling wall that is made of the magnetic material, and that is disposed on the magnetic memory element opposite to the printed circuit board.

In accordance with some embodiments of the present disclosure, the shielding unit further includes a plurality of supporting walls that supports the ceiling wall so as to permit the ceiling wall to be disposed over the magnetic memory element.

In accordance with some embodiments of the present disclosure, at least one of the supporting walls is made of the magnetic material.

In accordance with some embodiments of the present disclosure, at least one of the supporting walls is made of a non-magnetic material.

In accordance with some embodiments of the present disclosure, the supporting walls are connected to each other so as to permit the shielding unit to fully enclose the semiconductor chip on the printed circuit board.

In accordance with some embodiments of the present disclosure, at least two adjacent ones of the supporting walls are spaced apart from each other.

In accordance with some embodiments of the present disclosure, the printed circuit board has a top surface on which the semiconductor chip and the shielding unit are mounted. The shielding unit occupies an area on the top surface of the printed circuit board. The occupied area of the shielding unit ranges from a first value to a second value. When the occupied area of the shielding unit is the first value, the shielding unit is configured to permit the semiconductor chip to be fitted thereinside. When the occupied area of the shielding unit is the second value, the occupied area of the shielding unit is a surface area of the top surface of the printed circuit board.

In accordance with some embodiments of the present disclosure, the semiconductor chip is spaced apart from the shielding unit.

In accordance with some embodiments of the present disclosure, the semiconductor chip abuts the shielding unit.

In accordance with some embodiments of the present disclosure, the magnetic memory element is a magnetic random access memory.

In accordance with some embodiments of the present disclosure, the shielding unit has an outer surface distal from the magnetic memory element, and an inner surface opposite to the outer surface. The shielding unit is formed with a through hole that extends from the outer surface to the inner surface.

In accordance with some embodiments of the present disclosure, an electronic device includes a printed circuit board, a semiconductor chip, a magnet and a shielding unit. The semiconductor chip is mounted and electrically connected to the printed circuit board, and includes a magnetic memory element. The magnet is disposed to be spaced apart from the printed circuit board. The shielding unit is made of a magnetic material, and is mounted to the printed circuit board to at least partially cover the magnetic memory element so as to reduce interference from a magnetic field from the magnet on the magnetic memory element.

In accordance with some embodiments of the present disclosure, the shielding unit includes a ceiling wall and a plurality of supporting walls that support the ceiling wall. The ceiling wall and the supporting walls are connected to each other so as to permit the shielding unit to fully enclose the semiconductor chip on the printed circuit board.

In accordance with some embodiments of the present disclosure, the printed circuit board has a top surface on which the semiconductor chip and the shielding unit are mounted. The shielding unit occupies an area on the top surface of the printed circuit board. The occupied area of the shielding unit ranges from a first value to a second value. When the occupied area of the shielding unit is the first value, the shielding unit is configured to permit the semiconductor chip to be fitted thereinside. When the occupied area of the shielding unit is the second value, the occupied area of the shielding unit is a surface area of the top surface of the printed circuit board.

In accordance with some embodiments of the present disclosure, the magnetic memory element is a magnetic random access memory.

In accordance with some embodiments of the present disclosure, an electronic device includes a printed circuit board, a semiconductor chip, and a shielding unit. The semiconductor chip is mounted and electrically connected to the printed circuit board, and includes a magnetic memory element. The shielding unit is mounted to the printed circuit board and includes a plurality of supporting walls and a ceiling wall supported by the supporting walls. At least one of the ceiling wall and the supporting walls is made of a magnetic material and at least partially covers the magnetic memory element, so as to reduce interference from an external magnetic field on the magnetic memory element.

In accordance with some embodiments of the present disclosure, the ceiling wall and the supporting walls are made of the magnetic material. The supporting walls are connected to each other so as to permit the shielding unit to fully enclose the semiconductor chip on the printed circuit board.

In accordance with some embodiments of the present disclosure, the ceiling wall and the supporting walls are made of the magnetic material. At least two adjacent ones of the supporting walls are spaced apart from each other.

In accordance with some embodiments of the present disclosure, the magnetic material is one of silicon steel, manganese zinc, cobalt iron, nickel iron, and combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device comprising:
a printed circuit board;
a semiconductor chip mounted and electrically connected to the printed circuit board, and including a magnetic memory element; and
a shielding unit including a magnetic material, and mounted to the printed circuit board to at least partially cover the magnetic memory element so as to reduce interference from an external magnetic field on the magnetic memory element.

2. The electronic device according to claim 1, wherein the shielding unit includes a ceiling wall that is made of the magnetic material, and that is disposed on the magnetic memory element opposite to the printed circuit board.

3. The electronic device according to claim 2, wherein the shielding unit further includes a plurality of supporting walls that supports the ceiling wall so as to permit the ceiling wall to be disposed over the magnetic memory element.

4. The electronic device according to claim 3, wherein at least one of the supporting walls is made of the magnetic material.

5. The electronic device according to claim 3, wherein at least one of the supporting walls is made of a non-magnetic material.

6. The electronic device according to claim 3, wherein the supporting walls are connected to each other so as to permit the shielding unit to fully enclose the semiconductor chip on the printed circuit board.

7. The electronic device according to claim 3, wherein at least two adjacent ones of the supporting walls are spaced apart from each other.

8. The electronic device according to claim 1, wherein
the printed circuit board has a top surface on which the semiconductor chip and the shielding unit are mounted,
the shielding unit occupies an area on the top surface of the printed circuit board, the occupied area of the shielding unit ranging from a first value to a second value,
when the occupied area of the shielding unit is the first value, the shielding unit is configured to permit the semiconductor chip to be fitted thereinside, and
when the occupied area of the shielding unit is the second value, the occupied area of the shielding unit is a surface area of the top surface of the printed circuit board.

9. The electronic device according to claim 1, wherein the semiconductor chip is spaced apart from the shielding unit.

10. The electronic device according to claim 1, wherein the semiconductor chip abuts the shielding unit.

11. The electronic device according to claim 1, wherein the magnetic memory element is a magnetic random access memory.

12. The electronic device according to claim 1, wherein the shielding unit has an outer surface distal from the magnetic memory element, and an inner surface opposite to the outer surface, the shielding unit being formed with a through hole that extends from the outer surface to the inner surface.

13. An electronic device comprising:
a printed circuit board;
a semiconductor chip mounted and electrically connected to the printed circuit board, and including a magnetic memory element;
a magnet disposed to be spaced apart from the printed circuit board; and
a shielding unit made of a magnetic material, and mounted to the printed circuit board to at least partially cover the magnetic memory element so as to reduce interference from a magnetic field from the magnet on the magnetic memory element.

14. The electronic device according to claim 13, wherein the shielding unit includes a ceiling wall and a plurality of supporting walls that support the ceiling wall, the ceiling wall and the supporting walls being connected to each other so as to permit the shielding unit to fully enclose the semiconductor chip on the printed circuit board.

15. The electronic device according to claim 13, wherein
the printed circuit board has a top surface on which the semiconductor chip and the shielding unit are mounted,
the shielding unit occupies an area on the top surface of the printed circuit board, the occupied area of the shielding unit ranging from a first value to a second value,
when the occupied area of the shielding unit is the first value, the shielding unit is configured to permit the semiconductor chip to be fitted thereinside, and
when the occupied area of the shielding unit is the second value, the occupied area of the shielding unit is a surface area of the top surface of the printed circuit board.

16. The electronic device according to claim 13, wherein the magnetic memory element is a magnetic random access memory.

17. An electronic device comprising:
a printed circuit board;
a semiconductor chip mounted and electrically connected to the printed circuit board, and including a magnetic memory element; and
a shielding unit mounted to the printed circuit board and including a plurality of supporting walls and a ceiling wall supported by the supporting walls, at least one of the ceiling wall and the supporting walls being made of a magnetic material and at least partially covering the magnetic memory element, so as to reduce interference from an external magnetic field on the magnetic memory element.

18. The electronic device according to claim 17, wherein the ceiling wall and the supporting walls are made of the magnetic material, the supporting walls being connected to each other so as to permit the shielding unit to fully enclose the semiconductor chip on the printed circuit board.

19. The electronic device according to claim 17, wherein the ceiling wall and the supporting walls are made of the magnetic material, at least two adjacent ones of the supporting walls being spaced apart from each other.

20. The electronic device according to claim 17, wherein the magnetic material is one of silicon steel, manganese zinc, cobalt iron, nickel iron, and combinations thereof.
